(19) United States
(12) Patent Application Publication
(10) Pub. No.: US 2009/0142710 A1
(43) Pub. Date: Jun. 4, 2009

(54) METHOD FOR PATTERNING A PHOTORESIST LAYER

(75) Inventors: Cheng-Hsuan Lin, Taoyuan County (TW); Chao-Chun Huang, Changhua County (TW); Fuh-Yu Chang, Hsinchu County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 12/106,837

(22) Filed: Apr. 21, 2008

(30) Foreign Application Priority Data
Nov. 29, 2007 (TW) TW96145336

(51) Int. Cl. G03F 7/20

(52) U.S. Cl. 430/322

(57) ABSTRACT

The disclosed is a method for patterning a photoresist layer. An object is provided, a photoresist layer is formed on the object, and an ink pattern is printed on the photoresist layer. Shielded by the ink pattern, the photoresist is exposed and developed to be patterned. In addition, a layered material is optionally formed between the object and the photoresist layer.

### BACKGROUND OF THE INVENTION

1. Field of the Invention

The invention relates to a lithography process, and in particular, to replacing a conventional photomask with an ink pattern during the exposure step of the lithography process.

2. Description of the Related Art

In the semiconductor field, patterning of all types of layered material is one of a number of important topics. Certain methods cannot selectively pattern selective areas of the layered material, such as methods for forming the layered material such as deposition, evaporation, and sputtering, methods for removing the layered material such as dry or wet etching, and methods for doping the layered material such as ion implantation. Therefore, lithography is utilized for forming a patterned photoresist layer to further pattern the layered material. Modifying the lithography process is a continuing effort in the field, which includes modifying the light source wavelength of the exposure, the composition of the photoresist, and factors of the development flows. Nevertheless, all modifications still need a photomask during exposure. Generally, the photomask substrate is quartz or glass, and the shielding pattern formed on the substrate is metal such as chromium. If the described layered material is formed on a planar object such as silicon wafer, the transmitting area of the photomask pattern may reach a circle with a 12 inch diameter. If the described layered material is formed on a curved object such as a cylinder, the curved photomask and multiple exposures will be necessary and enormously enhance costs. For the LCD panel industry, large area lithography considerably enhances costs due to the large photomask used and corresponding equipment, with the lithography process also reducing plant utilization ratio. In addition, the metal such as chromium of the photomask results in environmental pollution, thereby failing to meet restriction of hazardous substances (RoHS) in places like Europe. Thus, it is expected that costs of improving the photomask material, should the photomask material be improved, would be enhanced. Lastly, the expensive conventional photomask increases test costs of research and development.

For solving the problems of the conventional photomask, U.S. Pat. No. 6,872,321 discloses an ink pattern serving as a passivation layer during copper film etching. However, different layered materials require different ink patterns, such that the ink of the method for one material cannot be applied on other various materials. For example, when copper film is replaced with silicon oxide, the ink pattern applied on the copper film may not efficiently adhere to the silicon oxide or serve as a passivation layer during silicon oxide etching.

Accordingly, a method to solve the problem for the conventional photomask is called for.

### SUMMARY OF THE INVENTION

The invention provides a method for patterning a photoresist layer, comprising providing an object, forming a photoresist layer on the object, printing an ink pattern on the photoresist layer, processing an exposure to the photoresist layer shielded by the ink pattern, and processing a development to pattern the photoresist layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1-5 are schematic views showing the processes of patterning the photoresist layer in one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

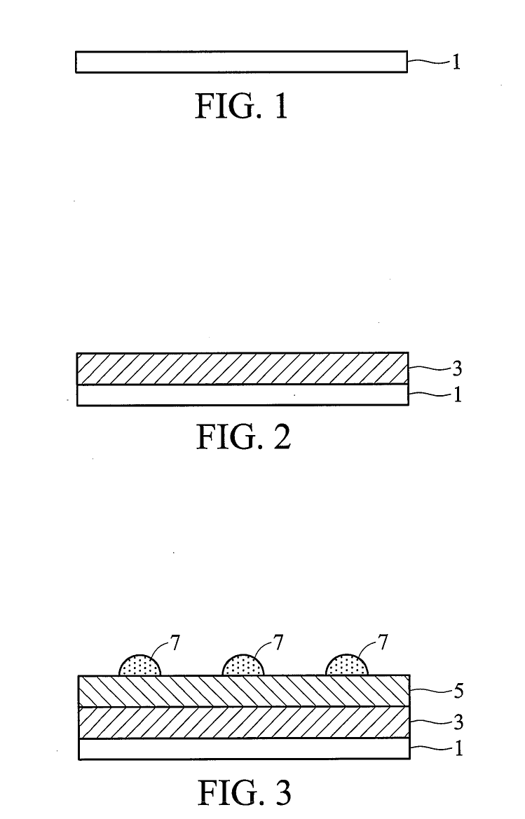

As shown in FIG. 1, an object 1 is provided. The object 1 in FIG. 1 is planar, however, in other embodiments, the object 1 can be curved such as a cylinder, a cone, a sphere, or other suitable shapes. The object 1 can be organic material such as plastic, rubber, or polymer, or inorganic material such as metal, metal oxide, or silicon wafer, or composites thereof.

As shown in FIG. 2, a layered material 3 is subsequently formed on the surface of the object 1. The composition of the layered material 3 and the object 1 may be similar or different. The layered material 3 includes described organic material, inorganic material, or composites thereof. In one embodiment, the layered material 3 is a single-layered structure. In another embodiment, the layered material 3 is a multi-layered structure.

As shown in FIG. 3, a photoresist layer 5 is subsequently formed on the layered material 3. The photoresist layer 5 can be positive type photoresist or negative type phoitoresist. For clarity of the descriptions, the photoresist layer 5 is a positive type photoresist in following Figs. It is understood that the negative type photoresist can be used in the invention. In one embodiment, the positive type photoresist is AZ4620 or AZ5214E commercially available from the Hoechst Celanese Corp. In another embodiment, the negative type photoresist is JSR-120N commercially available from the JSR Corp. The photoresist layer has a thickness of 1 μm to 80 μm. For example, the photoresist layer of AZ52141 has a thickness of 1 μm, and the double layered coating photoresist layer of JSR-120N has a thickness of 80 μm. The photoresist layer can be formed by spin-on.

The ink pattern 7 is then formed on the photoresist layer 5. The source of the ink in the invention depends on requirement. The ink can be commercial inkjet ink, or combinations of solvent, pigment, and additives. To smoothly print the ink from the printer to form the ink pattern 7, the ink composition should meet requirements of low viscosity and high surface tension. To efficiently shield the light source of the following exposure, the ink pattern 7 has an optical density (hereinafter OD) of 2.5 to 4.9. The OD of the chromium-containing photomask reaches 4.8, however, the light-shielding layer with an OD of 2.5 to 4.9 is effective. In one embodiment, the ink has an OD of 3.2. The OD of the ink pattern 7 is in direct proportion to the thickness of the ink pattern 7, and the OD can be changed by tuning the pigment concentration of the ink. The higher the ink concentration ink is, the higher the light-shielding effect is with a thinner ink pattern 7. In one embodiment, the ink pattern 7 has a thickness of 0.5 μm to 2 μm. Theoretically, the ink pattern 7 and the photoresist layer 5 have a contact angle equal to 90 degrees. Practically, the contact angle is less than 90 degrees, thereby causing the light-shielding difference between the center and edge of the ink pattern 7. If the light-shielding effect of the edge in the ink pattern is not enough, the photoresist layer 5 will be overexposed with narrower line width (positive type photoresist) or wider line width (negative type photoresist). The light-shielding effect can be improved by increasing the OD of the ink pattern 7, such as greater than 2.5. Lastly, the ink pattern 7 and the photoresist layer 5 do not dissolve with each other.

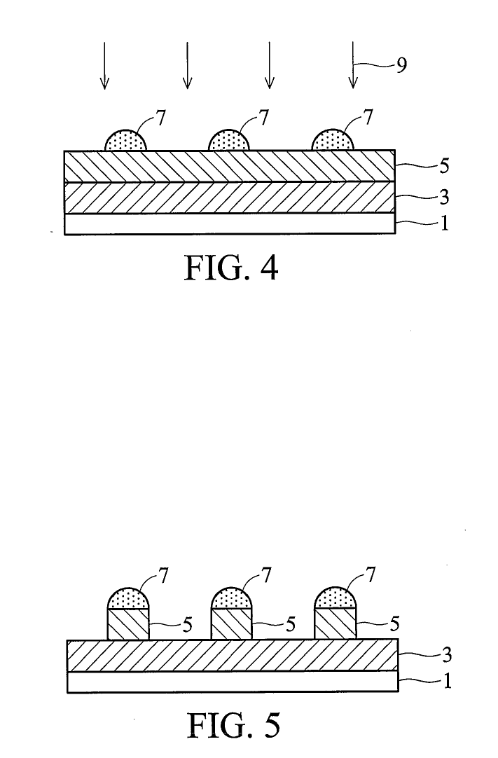

As shown in FIG. 4, an exposure is subsequently processed. The light source 9 of the exposure can be UV of the common photolithography process. As described above, the photoresist layer 5 in the Figures is positive type, and part of the photoresist layer 5 not shielded by the ink pattern 7 will be dissolved in the exposure. If the photoresist layer 5 adopts negative type photoresist, part of the photoresist layer 5 not shielded by the ink pattern 7 will be crosslinked in the exposure to form a reverse pattern.

As shown in FIG. 5, a development is then processed to remove part of the photoresist layer not shielded by the ink pattern 7. The type of developer solution depends on the type of the photoresist layer. In one embodiment, the ink pattern 7 will be removed in the development. In another embodiment, the ink pattern 7 is removed by an extra step. In a further embodiment, the ink pattern 7 can be retained without influencing the following processes and device performance. The patterned photoresist layer is completed whether the ink pattern 7 is retained or removed. Subsequently, the layered material 3 can be processed by etching, ion implantation, or any other commonly known steps if necessary. Note that the described processes has a layered material 3 disposed between the object 1 and the photoresist layer 5, however, the photoresist layer 5 can be directly formed on the surface of the object 1. After patterning of the photoresist layer 5, subsequently steps such as etching or ion implantation can be directly processed on the surface of the object 1.

Compared with the conventional photomask, the method for patterning the photoresist layer of the invention has the following advantages. First, the replacement of the chromium-containing photomask with ink reduces metal pollution. Next, the invention can be applied in a non-planar object with minimal required the new or updated equipment. Third, the invention is suitable for large area exposures. Lastly, ink costs are lower than photomask costs, especially when comparing the test stage.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for patterning a photoresist layer, comprising
providing an object;
forming a photoresist layer on the object;
printing an ink pattern on the photoresist layer;
processing an exposure to the photoresist layer shielded by the ink pattern; and
processing a development to pattern the photoresist layer.

2. The method as claimed in claim 1, wherein the object comprises a planar or a curved surface.

3. The method as claimed in claim 1, wherein the object comprises organic material, inorganic material, or composites thereof.

4. The method as claimed in claim 1, wherein the photoresist layer comprises positive type photoresist or negative type photoresist.

5. The method as claimed in claim 1, wherein the ink pattern and the photoresist layer have a contact angle substantially less than 90 degrees.

6. The method as claimed in claim 1, further comprising removing the ink pattern after patterning of the photoresist layer.

7. The method as claimed in claim 1, further comprising forming a layered material between the object and the photoresist layer.

8. The method as claimed in claim 7, wherein the layered material comprises organic material, inorganic material, or composites thereof.
